(19) United States
(12) Patent Application Publication
(10) Pub. No.: US 2018/0226535 A1
(43) Pub. Date: Aug. 9, 2018

(54) Methods of Forming Product Wafers Having Semiconductor Light-Emitting Devices To Improve Emission Wavelength Uniformity

(71) Applicant: Ultratech, Inc., San Jose, CA (US)

(72) Inventor: Andrew M. Hawryluk, Los Altos, CA (US)

(21) Appl. No.: 15/875,484

(22) Filed: Jan. 19, 2018

Related U.S. Application Data
(60) Provisional application No. 62/454,088, filed on Feb. 3, 2017.

(51) Int. Cl. H01L 33/00; H01S 5/30; H01L 21/66

(52) U.S. Cl. CPC H01L 33/0066; H01L 22/20; H01L 33/0079; H01S 5/3013

(57) ABSTRACT

Methods of forming product wafers having semiconductor light-emitting devices to improve emission wavelength uniformity include either estimating or measuring a spatial variation in the emission wavelengths of the light-emitting devices of an already formed product wafer. The methods can also include defining a corrective temperature distribution for feeding back to the upstream process to reduce variations in the emission wavelength when forming new product wafers. The method can further includes applying the corrective temperature distribution when forming the new product wafers so that the new product wafers have a higher yield in forming the light-emitting devices than the already formed product wafer.

### RELATED APPLICATION DATA

This application claims the benefit of priority of U.S. Provisional Patent Application Ser. No. 62/454,088, filed Feb. 3, 2017, and titled “METHODS OF FORMING PRODUCT WAFERS HAVING SEMICONDUCTOR LIGHT-EMITTING DEVICES TO IMPROVE EMISSION WAVELENGTH UNIFORMITY”, which is incorporated by reference herein in its entirety.

U.S. Pat. No. 8,765,493, entitled “Methods of characterizing semiconductor light-emitting devices based on product wafer characteristics,” is also incorporated herein by reference for its relevant teachings.

### FIELD

The present disclosure relates generally to the manufacturing of semiconductor light-emitting devices (LEDs) such as light-emitting diodes and laser diodes using product wafers, and in particular to methods of forming the product wafers so that the light-emitting devices have improved emission wavelength uniformity as a function of position of the light-emitting devices on the product wafer.

### BACKGROUND

Semiconductor LEDs such as light-emitting diodes and laser diodes are fast replacing conventional light sources in virtually the entire range of light and illumination applications. As a consequence, they are being manufactured in ever increasing numbers for a very wide range of emitted wavelengths.

Example semiconductor LEDs for general lighting are light-emitting diodes (also called “LEDs”) and diode lasers. A phosphor coating can be used to create a “white” light spectrum. The phosphor reacts with a specific emission wavelength of the device (e.g., a blue wavelength) and Stokes shifts a portion of the emission light from shorter to longer wavelengths to give the output light its white spectrum. A white spectrum can be characterized by an equivalent color temperature associated with the emitted light spectrum of the corresponding black-body radiation. A white-light spectrum that is “warm” is characterized by a color temperature of approximately 2800° K, whereas a “cold” white-light spectrum has a color temperature of approximately 5000° K. In a large number of applications, a warm white-light spectrum is preferred.

To obtain the proper color temperature, the emission wavelength λ_{E} of the semiconductor light-emitting device needs to be matched to the absorption and emission spectrum Δλ of the phosphor. Typically, the actual emission wavelength λ_{E} needs to be within +/−2 nm of the desired (select) emitted wavelength λ_{ED} to properly match with the phosphor absorption and emission characteristics. Properly matched, the LED lighting fixture provides a “white light” with a color temperature around 2800° K. LEDs that fall outside of the particular wavelength specification have considerably less value because they produce light that is “off-color” and hence less desirable by the consumer. An LED manufacturer will often sell these “off-color” LEDs into a less-color-critical application, such as a flashlight, or exterior parking-garage facility. However, the value of these LEDs is much less than those sold to the general household illumination market, where the color temperature is critical. For this reason, the LED manufacturer strives to manufacture more LEDs per wafer that are within the more-valuable spectral range.

For optimum yield and hence optimum value and profit, it is desirable to fabricate the semiconductor light-emitting devices so that they have an accurate emission wavelength to within a specified tolerance. Yet, measurements of product wafers to determine the emission wavelength of the light-emitting devices can reveal a large variation in the emission wavelength λ_{E} as a function of position on the product wafer. This spatial variation (non-uniformity) in the emission wavelength λ_{E} over the product wafer reduces the yield of the product wafers.

It would therefore be desirable to have methods of forming the product wafers to reduce or substantially eliminate the spatial variation in the light-emission wavelength, thereby increasing the yield of the product wafers.

### SUMMARY

An aspect of the disclosure is a method of forming from a substrate a new product wafer containing semiconductor light-emitting devices. The method includes a) either estimating or measuring a spatial variation in an emission wavelength λ_{E}(x,y) of light-emitting devices of an already formed second product wafer, wherein the spatial variation in the emission wavelength λ_{E}(x,y) is characteristic of a metalorganic chemical vapor deposition (MOCVD) process used to form the already formed product wafer; b) defining from the spatial variation in the emission wavelength λ_{E}(x,y) a corrective temperature distribution T_{C}(x,y) that can be applied to the substrate during the MOCVD process to reduce the emission-wavelength spatial variation λ_{E}(x,y) when forming the new product wafer; and c) performing the MOCVD process with the corrective temperature distribution T_{C}(x,y) applied to the substrate to form the new product wafer.

Another aspect of the disclosure is the method as described above, wherein the estimating or measuring of the spatial variation in the emission wavelength λ_{E}(x,y) includes estimating the spatial variation in the emission wavelength λ_{E}(x,y) by performing a surface stress measurement of the already formed product wafer using a stress measurement tool and then inferring the spatial variation in the emission wavelength λ_{E}(x,y) based on the surface stress measurement.

Another aspect of the disclosure is the method as described above, wherein the estimating or measuring of the spatial variation in the emission wavelength λ_{E}(x,y) includes measuring the spatial variation in the emission wavelength λ_{E}(x,y) by delivering power a plurality of the light-emitting devices to cause the light-emitting devices to emit light, and then measuring a spectral content of the emitted light from each of the plurality of the powered light-emitting devices.

Another aspect of the disclosure is the method as described above, wherein the performing of the MOCVD process includes: supporting the substrate in a substrate support region of a susceptor, wherein the substrate has a backside; and locally heating the substrate through the backside with an array of individually controllable heating elements operably disposed within the substrate support region.

Another aspect of the disclosure is the method as described above, wherein the substrate comprises sapphire.

Another aspect of the disclosure is the method as described above, wherein the performing of the MOCVD process includes depositing a layer of InGaAs on the substrate.

Another aspect of the disclosure is the method as described above, and further including: either estimating or measuring a spatial variation in the emission wavelength λ_{E}(x,y) of light-emitting devices formed in the product wafer formed from performing the MOCVD process; and repeating b) and c) on a different substrate to define another corrective temperature distribution T_{C}(x,y) and to form another product wafer.

Another aspect of the disclosure is the method as described above, wherein the light-emitting devices are either light-emitting diodes or laser diodes.

Another aspect of the disclosure is the method as described above, wherein the already formed product wafer was formed at a substantially uniform substrate temperature T_{S}, and wherein defining the corrective temperature T_{C}(x,y) in act b) includes making adjustments to the substantially uniform substrate temperature T_{S} by +1° C. for each −1 nm change δλ_{E} in the emission wavelength λ_{E} and by −1° C. for each +1 nm change δλ_{E} in the emission wavelength λ_{E}.

Another aspect of the disclosure is the method as described above, wherein the corrective temperature profile T_{C}(x,y) has a maximum temperature gradient of 2° C./cm.

Another aspect of the disclosure is a method of making a light-emitting apparatus. The method includes: forming a new product wafer using the method of claim 1; dicing the new product wafer to form individual dies that each includes at least one of the light-emitting devices; and operably incorporating at least one of the individual dies into a light-emitting apparatus.

Another aspect of the disclosure is a method of forming from a substrate a new product wafer having semiconductor light-emitting devices. The method includes: estimating a spatial variation in an emission wavelength λ_{E}(x,y) from light-emitting devices of an already formed product wafer by performing a surface stress measurement of the already formed product wafer using a stress measurement tool and then inferring the spatial variation in the emission wavelength λ_{E}(x,y) based on the surface stress measurement, wherein the spatial variation in the emission wavelength λ_{E}(x,y) is characteristic of a metalorganic chemical vapor deposition (MOCVD) process used to form the already formed product wafer; defining from the spatial variation in the emission wavelength λ_{E}(x,y) a corrective temperature distribution T_{C}(x,y) that can be applied to the substrate during the metalorganic chemical vapor deposition (MOCVD) process to reduce the emission-wavelength spatial variation λ_{E}(x,y) when forming the new product wafer; and performing the MOCVD process with the corrective temperature distribution T_{C}(x,y) applied to the substrate to form the new product wafer.

Another aspect of the disclosure is the method as described above, wherein the already formed product wafer was formed at a substantially uniform substrate temperature T_{S}, and wherein defining the corrective temperature T_{C}(x,y) in act b) includes making adjustments to the substantially uniform substrate temperature T_{S} by +1° C. for each −1 nm change δλ_{E} in the emission wavelength λ_{E} and by −1° C. for each +1 nm change δλ_{E} in the emission wavelength λ_{E}.

Another aspect of the disclosure is the method as described above, wherein the corrective temperature profile T_{C}(x,y) has a maximum temperature gradient of 2° C./cm.

Another aspect of the disclosure is a method of making a light-emitting apparatus. The method includes: forming a new product wafer using the method of claim 12; dicing the new product wafer to form individual dies that each includes at least one of the light-emitting devices; and operably incorporating at least one of the individual dies into a light-emitting apparatus.

Additional features and advantages of the disclosure are set forth in the detailed description that follows, and in part will be readily apparent to those skilled in the art from that description or recognized by practicing the disclosure as described herein, including the detailed description that follows, the claims, and the appended drawings. The claims are incorporated into and constitute part of the detailed description of the disclosure.

It is to be understood that both the foregoing general description and the following detailed description present embodiments of the disclosure and are intended to provide an overview or framework for understanding the nature and character of the disclosure as it is claimed. The accompanying drawings are included to provide a further understanding of the disclosure and are incorporated into and constitute a part of this specification. The drawings illustrate various embodiments of the disclosure and together with the description serve to explain the principles and operations of the disclosure.

### BRIEF DESCRIPTION OF THE DRAWINGS

FIG. 1 is a plan view of an example product wafer used in the formation of semiconductor light-emitting devices;

FIG. 2 is a combined cross-sectional view and enlarged partial view of the example product wafer of FIG. 1;

FIG. 3 is an elevated isometric view of an example light-emitting apparatus that includes a die from the product wafer as formed using the methods disclosed herein, with the die being highlighted in an enlarged isometric view;

FIG. 4 shows a collection of substrates supported in a susceptor for use in the metalorganic chemical vapor deposition (MOCVD) reactor system of FIG. 5;

FIG. 5 is a schematic diagram of an MOCVD reactor system used to form the device layer atop the substrate when forming the product wafer of FIG. 2;

FIG. 6A is a top-down view of a portion of the susceptor used in the MOCVD reactor system of FIG. 5;

FIG. 6B is a diagram containing a cross-sectional view of the portion of the susceptor shown in FIG. 6A, and also showing a controller configured to individually control the heating elements;

FIGS. 7A through 7D are plan views of an example product wafer showing contours of variations in the product wafer temperature T, device dimension D, device-layer stress S and emission wavelength λ_{E}, respectively;

FIG. 8A contains a plan view of a product wafer illustrating contours that show spatial variations in the product wafer emission wavelength λ_{E} (λ_{E}(x,y)) of the light-emitting devices along with a close-up view of some of the light-emitting devices of the product wafer;

FIG. 8B is a plan view of a product wafer illustrating showing contours of the estimated or measured emission wavelengths 4, wherein the wavelength contours of 457 nm and 455 nm are in bold because they represent the boundaries within which resides device structures having a desired wavelength λ_{ED} of 456 nm+/−1 nm; and

FIG. 9 is contour plot of an example corrective temperature distribution T_{C}(x,y) that can be used to process substrates in the MOCVD system to form new product wafers having a reduced spatial variation in the emission wavelength λ_{E} as compared to previously formed product wafers, wherein the corrective temperature distribution T_{C}(x,y) is based on the downstream measurements of the emission wavelength λ_{E} as shown in FIG. 8B.

Cartesian coordinates are shown in some of the Figures for the sake of reference and are not intended as being limiting as to orientation or configuration.

### DETAILED DESCRIPTION

Reference is now made in detail to the present preferred embodiments of the disclosure, examples of which are illustrated in the accompanying drawings. Whenever possible, the same reference numbers and symbols are used throughout the drawings to refer to the same or like parts. The claims are incorporated into and constitute part of this detailed description.

In the discussion herein, the initialism “LED” is generally understood to mean “light-emitting device,” but it can also mean “light-emitting diode,” and one skilled in the art will understand the difference based on the context in which this initialism is used. A “light-emitting apparatus” is an apparatus that employs one or more light-emitting devices, which can be in the form of one or more dies from a diced product wafer formed using the methods disclosed herein.

The terms “downstream” and “upstream” are used herein to denote the position of a process step, wherein an “upstream” process step occurs sooner than a “downstream” process step, so that a “downstream” product wafer has undergone more process steps than an “upstream” product wafer. In the methods disclosed herein, a “downstream” product wafer refers to a product wafer that has been completely processed (“already formed” or “previously formed”) and is the subject of emission wavelength measurements to be used for feeding back upstream into the process that forms the “new” product wafers.

Product Wafer

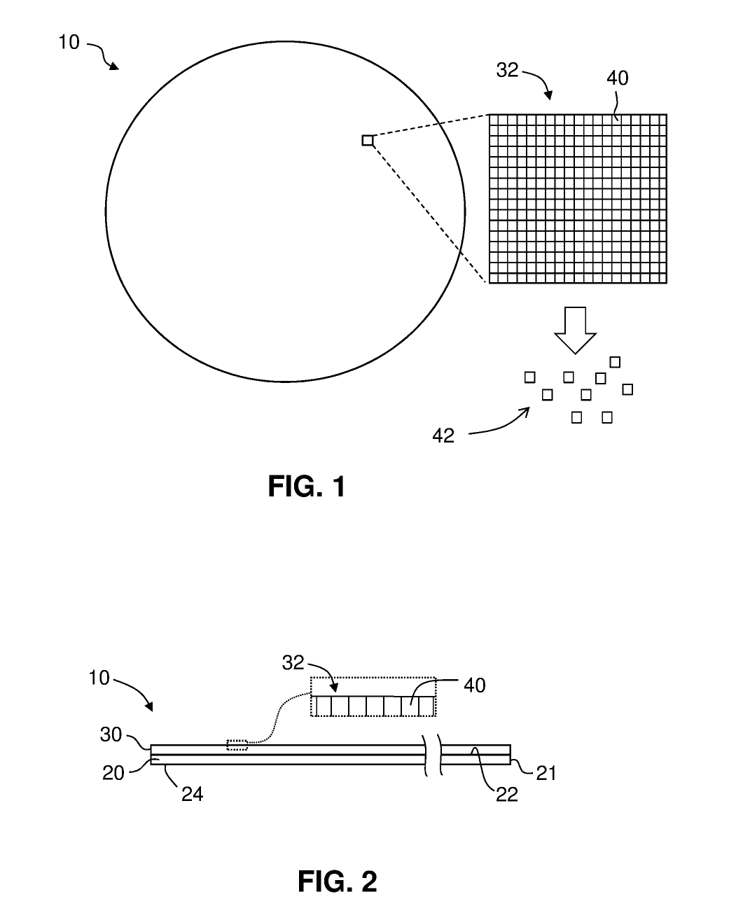

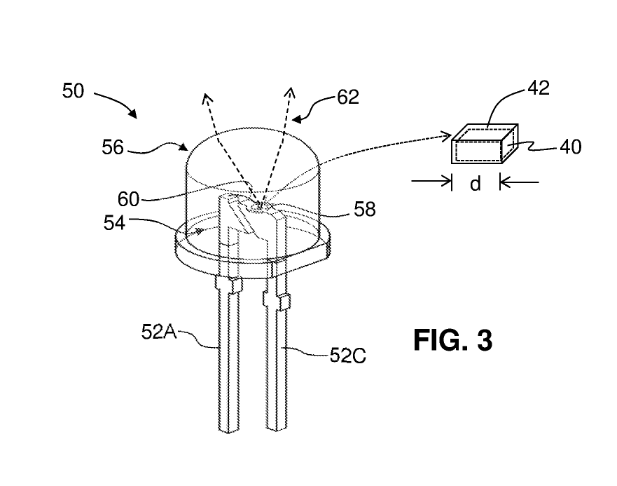

FIG. 1 is a plan view and FIG. 2 is a cross-sectional view of an example product wafer 10 used to form semiconductor LEDs, such as light-emitting diodes, and laser diodes. Here, the term “product wafer” generally means a wafer or a substrate on which device structures are formed, and wherein the device structures can define light-emitting devices that, in an example, can be used to form an LED product or apparatus.

The example product wafer 10 comprises a semiconductor substrate 20 having an edge 21, a top surface 22 and a bottom surface or backside 24, with a device layer 30 formed on the top surface 22. An example semiconductor substrate 20 is made of sapphire or silicon. An example product wafer 10 has a diameter of 2 to 6 inches when substrate 20 comprises sapphire substrate 20 and a diameter of 6 to 12 inches when the substrate 20 is silicon. The device layer 30 comprises an array 32 of semiconductor light-emitting device (“light-emitting devices”) 40. In an example, a product wafer 10 includes many thousands of light-emitting devices 40, which in an example can have a size of about 1 mm×1 mm. The light-emitting devices 40 have associated therewith an actual emission wavelength λ_{E} and an output spectrum Δλ_{E} that is associated with the aforementioned color temperature. The desired or select emission wavelength for light-emitting devices 40 is λ_{ED}.

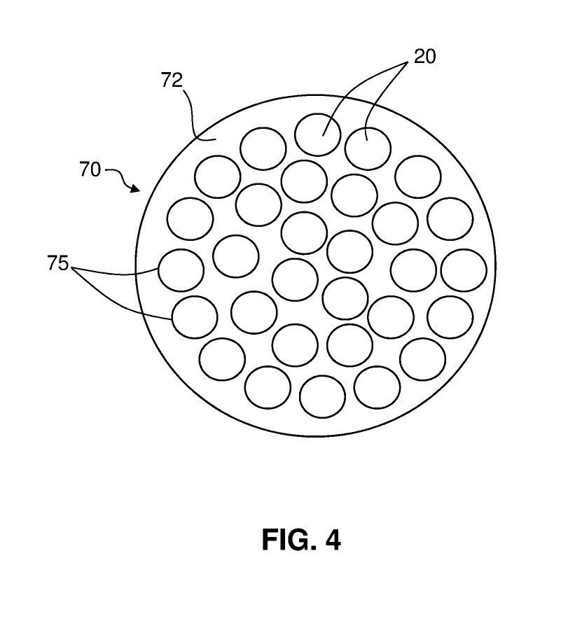

Once product wafer 10 is completely formed so that the light-emitting devices 40 are functional, the product wafer 10 is cut (“diced”) so that the individual light-emitting devices 40 in the array 32 are separated as individual dies 42, i.e., each die 42 includes at least one light-emitting device 40. With reference to FIG. 3, one or more of the dies 42 can then be used form a light-emitting apparatus 50. The light-emitting apparatus 50 of FIG. 3 includes an anode 52A and a cathode 52C that extend into an interior 54 of an epoxy lens casing 56. The cathode 52C includes a reflective cavity 58 in which the die 42 resides. Wire bonds 60 electrically connect the anode 52A and the cathode 52C to the die. A power source (not shown) connects to the anode 52A and the cathode 52C to provide the electricity needed to power the die 42 so that it light-emitting device 40 therein emits light 62 at its wavelength λ_{E}. The light-emitting apparatus 50 of FIG. 3 is a prior art device when the die 42 is a prior art die, but is not a prior art device when the die 42 is formed from a product wafer 10 using the methods disclosed herein.

Example light-emitting devices 40 are the form of LEDs that are fabricated by growing GaN on a sapphire substrate 20. The GaN is grown using a metalorganic chemical vapor deposition (MOCVD) process. The MOCVD process is carried out in a MOCVD reactor and is performed in a manner that results in the formation of multi-quantum-well structures (not shown).

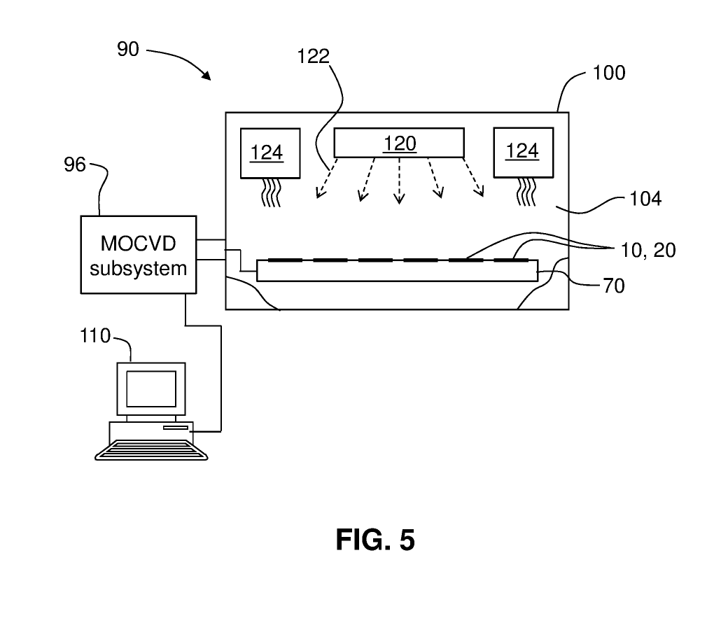

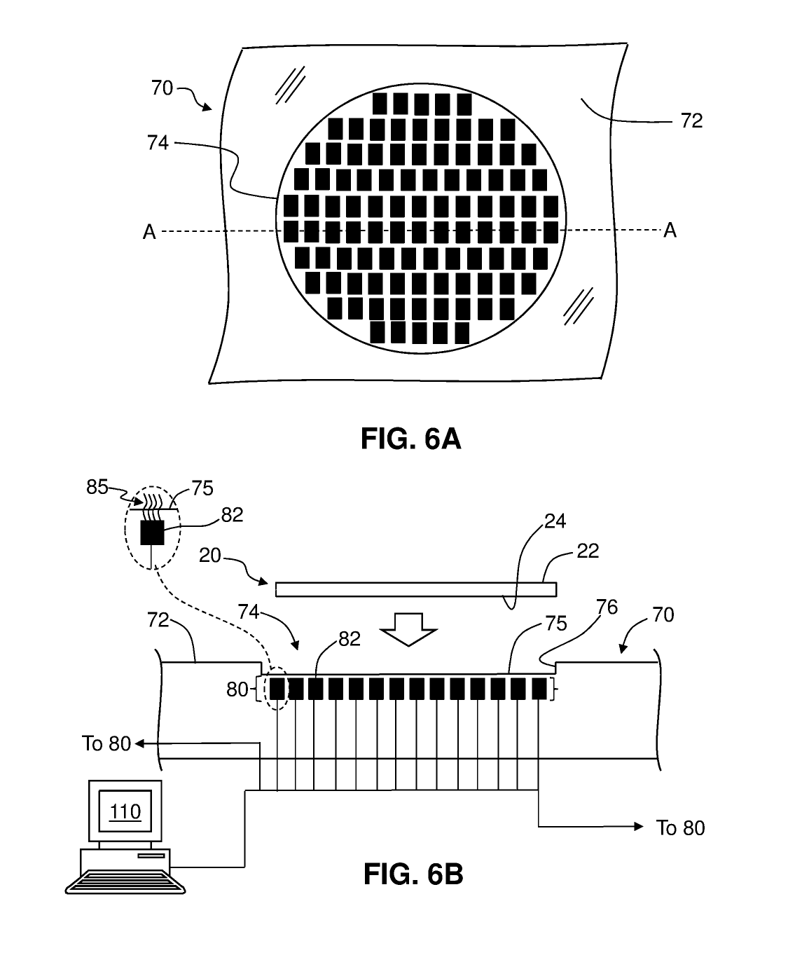

FIG. 4 shows a collection of substrates 20 supported in a substrate holder or a susceptor 70 in the form of a platen having a top surface 72 and multiple substrate support regions 74 that each support one of the substrates 20. FIG. 5 shows a MOCVD reactor system 90 having reactor chamber 100 operably connected to a MOCVD subsystem 96. The MOCVD subsystem 96 includes the various MOCVD system components (not shown), such as a vacuum pump, gas sources, a venting system, a baratron, etc. The MOCVD chamber 100 has an interior 104 in which the susceptor 70 and substrates 20 reside when the MOCVD process is performed to form product wafers 10 from the substrates. Note that after the MOCVD process is performed, the substrates 20 become product wafers 10. The MOCVD reactor system 90 includes a controller 110 operably coupled to the MOCVD subsystem 96. The controller 110 is configured to control the MOCVD process that occurs in the interior 104 of the chamber 100.

The MOCVD process is performed at elevated temperatures T_{E} (e.g., at about 1000° C.). The susceptor 70 typically rotates at high speed under a nozzle 120 that showers reaction gas or gases 122 onto the substrate top surface 22. In an example, the elevated temperature T_{E} in the chamber 100 is achieved using one or more heat sources 124 within the interior 104. The one or more heat sources 124 can comprise one or more heating coils, one or more heat lamps, etc., or any combination thereof. This heating creates a temperature distribution T(x,y) over each substrate 20 (in the local coordinate system of each substrate), which in the conventional art is understood as preferably being as uniform as possible. Thus, in an example, the elevated temperature T_{E} causes each substrate 20 to have a substantially uniform substrate temperature T(x,y)=T_{S}.

An aspect of the disclosure includes methods of forming the product wafers 10 by controlling the temperature distribution T(x,y) of each substrate 20 more closely than can be done using just the heat sources 124 that provides the elevated reactor temperature T_{E} but that cannot be used to locally control the temperature distribution T(x,y) over each substrate.

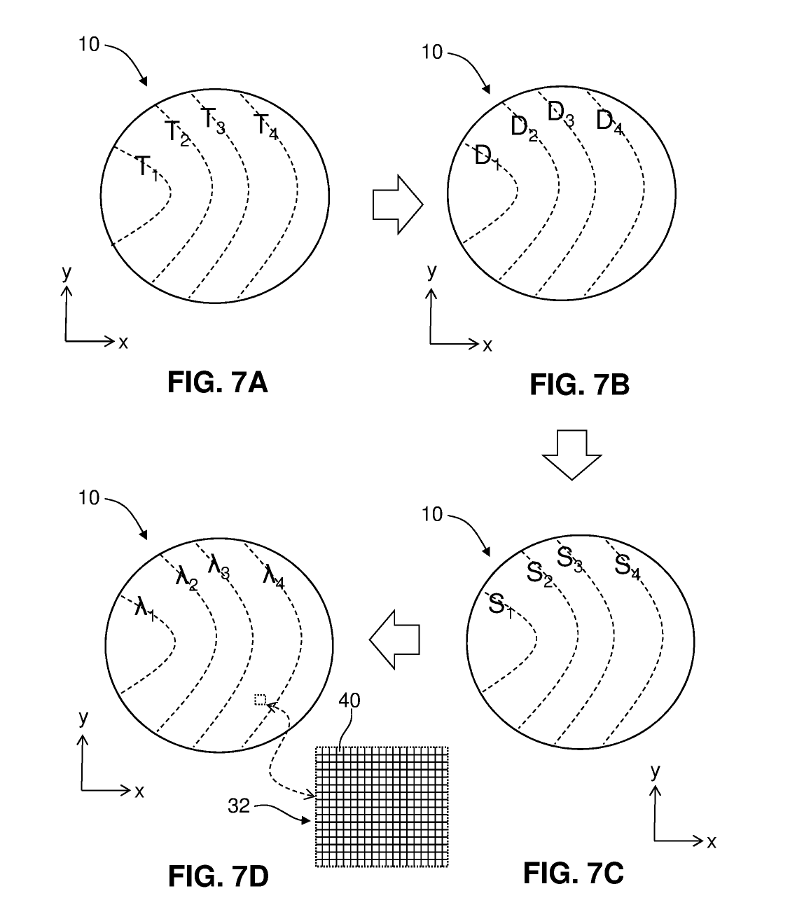

FIG. 6A is a top-down view of a portion of the susceptor 70 of FIG. 4 showing one of the substrate support regions 74. FIG. 6B is a cross-sectional view of the portion of the susceptor 70 of FIG. 6A taken along the line A-A. FIG. 6B also shows the substrate 20 positioned above the substrate support region 74 so that it can be operably disposed in the substrate support region. In an example, each substrate support region 74 is in the form of a recess having a recessed surface 75 that resides below the top surface 72, with the recess having an outer edge 76.

The susceptor 70 further includes an array 80 of heating elements 82 arranged at or just below the recessed surface 75. The heating element can be used, for example, to define a corrective temperature distribution that reduces the spatial variability in the light-emission wavelength over a product wafer, such as product wafer 10, based on feedback emission-wavelength measurements or estimations from a downstream (i.e., already formed) product wafer. The heating elements 82 are operably connected to a controller 110, which is configured to individually control the heating elements to generate a select amount of heat 85 (see close-up inset of FIG. 6B) to define a desired temperature distribution T(x,y) for the substrate 20 during the process of forming the product wafer 10, as described below. Due to the diffusion of the heat 85 from each of the heating elements 82, the temperature distribution T(x,y) imparted to the substrate 20 is not sharply defined. However, as discussed below, the temperature distribution T(x,y) required for reducing the spatial variation in the emission wavelength λ_{E}(x,y) can be slowly varying and generally does not require abrupt temperature changes.

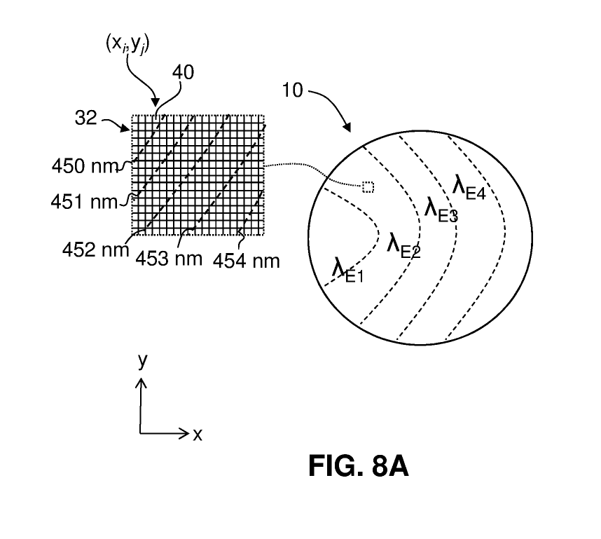

In particular, the controller 110 is used to carefully control the temperature distribution T(x,y) of product wafers 10 because the actual emission wavelength λ_{E} varies considerably as a function of the MOCVD growth conditions. FIGS. 7A through 7D are plan views of an example product wafer 10, schematically illustrating example contours of temperature distribution T(x, y), device dimension D(x,y), device-layer stress S(x,y) and the (actual) emission wavelength λ_{E}(x,y), respectively. Here, the temperature distribution T(x,y) refers to either the substrate temperature or the product wafer temperature, since the substrate 20 is undergoing processing to form the product wafer 10. The discussion below refers simply to “product wafer temperature” for ease of discussion.

As the product wafer temperature T(x,y) changes (FIG. 7A), the device dimensions D(x,y), e.g., the thickness of the multi-quantum well structures (not shown) formed during the MOCVD process, change in a corresponding manner (FIG. 7B). This also translates into a corresponding change in device-layer stress S(x,y) over the product wafer 10 (FIG. 7C), which in turn results in a corresponding change the actual emission wavelength λ_{E} (x,y) (FIG. 7D).

In certain cases, a 1° C. temperature change in the product wafer temperature T can lead to an approximate shift δλ_{E} of 1 nm in the emission wavelength λ_{E}. Hence, it becomes desirable to either estimate or measure, and eventually control, the temperature non-uniformities and temperature repeatability in the MOCVD reactor system 90 to ensure proper control of the product wafer temperature T(x,y). Temperature non-uniformities on a product wafer can lead to local changes in growth conditions, which can result in variations in the LED emission wavelength.

In present-day, MOCVD-based manufacturing of light-emitting devices 40, the actual emission wavelength λ_{E} and the corresponding emission wavelength uniformity over the product wafer 10 is unknown until the light-emitting devices are wired and powered up and the light emitted from the light-emitting devices is measured, i.e., spectrally analyzed. This is a costly and time-consuming process.

Currently, to estimate or predict the LED emission wavelength λ_{E}, substrates are inspected with a photoluminescent technique, where a short wavelength source (typically 248 nm) is made incident upon the multi-quantum well region to excite emission. However, a significant limitation of this technique is that it is a point-by-point inspection technique. To accurately map an entire product wafer with high spatial resolution (e.g., a spatial resolution smaller than a die size) takes from 30 minutes to 240 minutes, depending on the substrate size used to form the product wafer.

A further limitation of this technique is that the emission wavelength from photoluminescence is generally not the same emission wavelength λ_{E} from the LED during electrical stimulation. The source of this difference is believed to be from the additional manufacturing steps that the LED undergoes between the photoluminescence inspection and the final product. Typically, there is an offset between the photoluminescence emission wavelength and the electrically stimulated LED emission wavelength that is pre-measured in production.

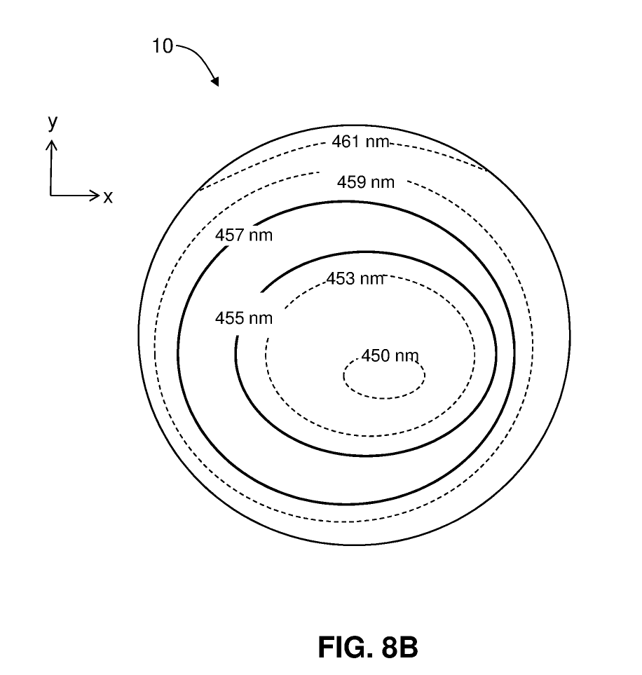

FIG. 8A is a plan view an example product wafer 10 schematically illustrating example contours of actual emission wavelength λ_{E}(x,y). One particular light-emitting device 40 is shown having a position (xᵢ,yᵢ), which is measured relative to a reference location, e.g., the center of the product wafer. The close-up inset of array 32 of light-emitting devices 40 shows more detailed (i.e., closely-spaced) contours λ_{E} of the actual emission wavelength λ_{E} in 1 nm increments. In an example, variations (shifts) in the emission wavelength of &_{E} of 1 nm can be estimated or predicted.

FIG. 8B is a plan view of a hypothetical product wafer 10, showing example 2 nm contours of predicted (estimated) or measured emission wavelength λ_{E} wherein the product wafer 10 has a concave or bowl-shaped curvature C(x,y). Assuming a desired emission wavelength of λ_{ED}=456 nm with an emission wavelength variation tolerance δλ of +/−1 nm, the wavelength contours of FIG. 8B show those dies 42 from light-emitting devices 40 having (x,y) positions within the 455 nm and 457 nm wavelength contours, which are shown as solid lines (i.e., within the emission-wavelength variation tolerance δλ). Thus, in an example, a first number of light-emitting devices 40 fall within the 455 nm and 457 nm contours and a second number of LED structures 40 fall outside of these contours. It would be desirable to have most or all the light-emitting devices 40 fall within the wavelength variation tolerance δλ of +/−1 nm of the desired emission wavelength λ_{ED}=456 nm so that the product wafer yield is greater, or better yet maximum.

Feedback Control of the Process Temperature

Once the variation in the emission wavelength λ_{E} (x,y) of the light-emitting devices 40 of the product wafer 10 is established such as shown in FIG. 7A, 8A or 8B, this information can be fed back into the process to adjust the temperature profile T(x,y) for the next (“new”) product wafer 10 to be processed in the MOCVD reactor system 90. In particular, the temperature profile T(x,y) is adjusted to define a corrective temperature profile T_{C}(x,y) that results in a change in the deposition conditions when forming the upstream (new) product wafers 10 to at least partially counter the deposition conditions that cause the undesired variation in the emission wavelengths 4 seen in measurements or predicted performance made on the already formed (downstream) product wafers. Thus, the corrective temperature profile T_{C}(x,y) results in a reduction in the spatial variation in the emission wavelength λ_{E}(x,y) for the new product wafer as compared to the downstream (i.e., already formed) product wafer that was measured to provide the feedback information.

For example, manufacturing of the GaN LED involves growing a layer of InGaAs. In places where the substrate temperature 10 is higher (i.e., “hotter”), the Indium (In) “boils off” more readily than in places where the substrate temperature is lower (“cooler”). Thus, the hotter regions have a lower density of In than the cooler regions. The lower indium content results in a shorter emission wavelength λ_{E}.

Thus, an example of the feedback control of the process for forming product wafers 10 in a manner that reduces a variation in the emission wavelength λ_{E} of the light-emitting devices 40 formed thereon includes the following steps. The first step is to form a product wafer 10 having the light-emitting devices 40 using the MOCVD reactor system 90, with the heater elements 82 set (e.g., by controller 110) to provide substantially uniform heating of each substrate 20. The second step is then to measure or predict (e.g., infer or estimate from surface stress measurements) the light-emission wavelengths λ_{E} of at least a portion of the light-emitting devices 40 of the product wafer to determine the variation in the light-emission wavelength as a function of (x,y) position on the product wafer, i.e., λ_{E}(x,y) to the desired spatial resolution over the product wafer. It is assumed that the spatial variation in the emission wavelength λ_{E}(x,y) is a characteristic of the MOCVD process used to form the product wafer and will be present in substantially the same form in subsequently processed product wafers.

The third step is to define a corrective temperature distribution T_{C}(x,y) that can be applied to forming another (new) product wafer 10 that has better emission-wavelength uniformity than the already formed product wafer. Generally, the corrective temperature distribution T_{C}(x,y) is cooler where the light-emission wavelengths 4 are shorter and hotter where the light-emission wavelengths 4 are longer to counteract the adverse effects of the InGaAs deposition during the MOCVD process. In an example, the general spatial variation in the corrective temperature distribution T_{C}(x,y) is known but the precise temperature values at each (x,y) position needed to minimize the variation in the light-emission wavelengths 4 may not be known precisely. In this circumstance, the corrective temperature distribution T_{C}(x,y) can be established empirically, e.g., by up to between two and five few iterations of the feedback loop. In an example, an initial corrective temperature distribution T_{C}(x,y) is formed by assigning a 1° C. temperature change to make a change δλ_{E} of 1 nm in the emission wavelength λ_{E}, with a +1° C. change causing a −1 nm change δλ_{E} and a −1° C. change causing a +1 nm change &_{E}.

The fourth step is to apply the corrective temperature distribution T_{C}(x,y) to the substrate 20 used to form the new product wafer 10 so that the light-emitting devices 40 of the new product wafer exhibit less spatial variation in the light-emission wavelength λ_{E}(x,y) over the second product wafer. This can result in a substantially improved yield for the new product wafer as compared to the already formed product wafer.

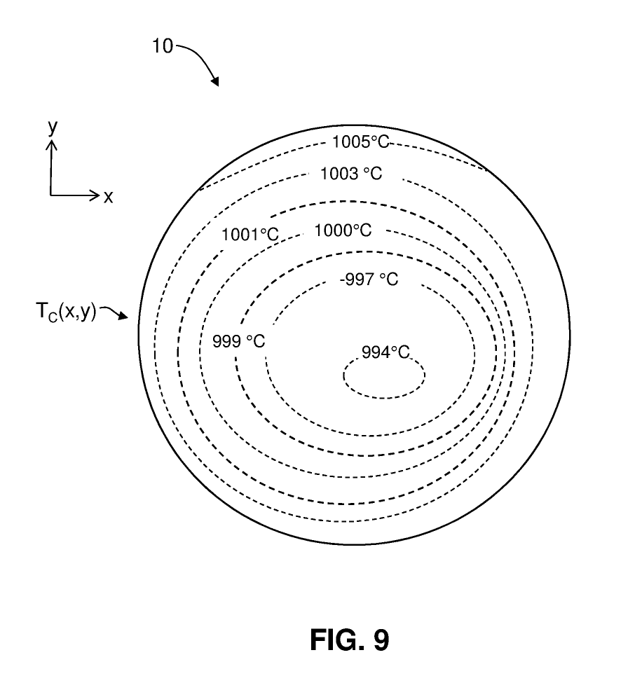

FIG. 9 shows an example of a corrective temperature distribution T_{C}(x,y) that can be used to reduce the variation in the light-emission wavelength λ_{E} of the light-emitting devices 40 associated with the product wafer 10 of FIG. 8B, wherein T_{S}=1000° C. is assumed to be the elevated temperature T_{E} of the reactor chamber 100 as well as the substrate temperature at which the desired light-emission wavelength λ_{E}=456 nm was obtained. The maximum temperature variation over the product wafer 10 for the corrective temperature distribution T_{C}(x,y) of FIG. 9 is 11° C., which is easily obtained using array 80 of heating elements 82. Note also that the change in temperature (i.e., the temperature gradient) is relative smooth and slowly varying.

In an example, when the product wafer 10 has a diameter of 300 mm, and assuming that the 11° C. variation starts from the center of the product wafer and moves outward (similar to FIG. 9), the maximum temperature variation of 11° C. occurs over 150 mm, which is approximate temperature gradient of about 0.7° C. every centimeter. Temperature gradients on this order (e.g., 2° C./cm or less) can easily be achieved using the array 80 of heating elements 82. Likewise, the corrective temperature T_{C}(x,y) is only a minor perturbation relative to the otherwise substantially uniform substrate temperature T_{S} during MOCVD processing. In an example, the array 80 of heating elements 82 is used in part to provide a “DC” heating component to the substrate 20 to help raise the substrate 20 to a base temperature as well as the varying or “AC” heating component used to define the corrective temperature T_{C}(x,y).

It will be apparent to those skilled in the art that various modifications and variations can be made to the present disclosure without departing from the spirit and scope of the disclosure. It is intended that the present disclosure cover the modifications and variations of this disclosure provided they fall within the scope of the appended claims and their equivalents.

What is claimed is:

1. A method of forming from a substrate a new product wafer containing semiconductor light-emitting devices, the method comprising:
a) either estimating or measuring a spatial variation in an emission wavelength λ_{E}(x,y) of light-emitting devices of an already formed product wafer, wherein the spatial variation in the emission wavelength λ_{E}(x,y) is characteristic of a metalorganic chemical vapor deposition (MOCVD) process used to form the already formed first product wafer;
b) defining from the spatial variation in the emission wavelength λ_{E}(x,y) a corrective temperature distribution T_{C}(x,y) that can be applied to the substrate during the MOCVD process to reduce the emission-wavelength spatial variation λ_{E}(x,y) when forming the new product wafer; and
c) performing the MOCVD process with the corrective temperature distribution T_{C}(x,y) applied to the substrate to form the new product wafer.

2. The method according to claim 1, wherein the estimating or measuring of the spatial variation in the emission wavelength λ_{E}(x,y) comprises estimating the spatial variation in the emission wavelength λ_{E}(x,y) by performing a surface stress measurement of the already formed product wafer using a stress measurement tool, and then inferring the spatial variation in the emission wavelength λ_{E}(x,y) based on the surface stress measurement.

3. The method according to claim 1, wherein the estimating or measuring of the spatial variation in the emission wavelength λ_{E}(x,y) comprises measuring the spatial variation in the emission wavelength λ_{E}(x,y) by delivering power a plurality of the light-emitting devices to cause the light-emitting devices to emit light, and then measuring a spectral content of the emitted light from each of the plurality of the powered light-emitting devices.

4. The method according to claim 1, wherein the performing of the MOCVD process includes:
supporting the substrate in a substrate support region of a susceptor, wherein the substrate has a backside; and
locally heating the substrate through the backside with an array of individually controllable heating elements operably disposed within the substrate support region.

5. The method according to claim 1, wherein the substrate comprises sapphire.

6. The method according to claim 1, wherein the performing of the MOCVD process includes depositing a layer of InGaAs on the substrate.

7. The method according claim 1, further comprising:
either estimating or measuring a spatial variation in the emission wavelength λ_{E}(x,y) of light-emitting devices formed in the product wafer formed from the performing the MOCVD process; and
repeating b) and c) on a different substrate to define another corrective temperature distribution T_{C}(x,y) and to form another product wafer.

8. The method according to claim 1, wherein the light-emitting devices are either light-emitting diodes or laser diodes.

9. The method according to claim 1, wherein the already formed product wafer was formed at a substantially uniform substrate temperature T_{S}, and wherein defining the corrective temperature T_{C}(x,y) in act b) includes making adjustments to the substantially uniform substrate temperature T_{S} by +1° C. for each −1 nm change δλ_{E} in the emission wavelength λ_{E} and by −1° C. for each +1 nm change δλ_{E} in the emission wavelength λ_{E}.

10. The method according to claim 1, wherein the corrective temperature profile T_{C}(x,y) has a maximum temperature gradient of 2° C./cm.

11. A method of making a light-emitting apparatus, the method comprising:
forming a new product wafer using the method of claim 1;
dicing the new product wafer to form individual dies that each includes at least one of the light-emitting devices; and
operably incorporating at least one of the individual dies into a light-emitting apparatus.

12. A method of forming from a substrate a new product wafer having semiconductor light-emitting devices, the method comprising:
estimating a spatial variation in an emission wavelength λ_{E}(x,y) of light-emission devices of an already formed product wafer by performing a surface stress measurement of the already formed product wafer using a stress measurement tool and then inferring the spatial variation in the emission wavelength λ_{E}(x,y) based on the surface stress measurement, wherein the spatial variation in the emission wavelength λ_{E}(x,y) is characteristic of a metalorganic chemical vapor deposition (MOCVD) process used to form the already formed product wafer;
defining from the spatial variation in the emission wavelength λ_{E}(x,y) a corrective temperature distribution T_{C}(x,y) that can be applied to the substrate during the MOCVD process to reduce the emission-wavelength spatial variation λ_{E}(x,y) when forming the new product wafer; and
performing the MOCVD process with the corrective temperature distribution T_{C}(x,y) applied to the substrate to form the new product wafer.

13. The method according to claim 12, wherein the already formed product wafer was formed at a substantially uniform substrate temperature T_{S}, and wherein defining the corrective temperature T_{C}(x,y) in act b) includes making adjustments to the substantially uniform substrate temperature TS by +1° C. for each −1 nm change δλ_{E} in the emission wavelength λ_{E} and by −1° C. for each +1 nm change δλ_{E} in the emission wavelength λ_{E}.

14. The method according to claim 1, wherein the corrective temperature profile T_{C}(x,y) has a maximum temperature gradient of 2° C./cm.

15. A method of making a light-emitting apparatus, the method comprising:
forming a new product wafer using the method of claim 12;
dicing the new product wafer to form individual dies that each includes at least one of the light-emitting devices; and
operably incorporating at least one of the individual dies into a light-emitting apparatus.
